(19) United States
(12) Patent Application Publication
(10) Pub. No.: US 2006/0279979 A1
(43) Pub. Date: Dec. 14, 2006

(54) Method of reading phase-change memory elements

(76) Inventors: Tyler Lowrey, San Jose, CA (US); Ward Parkinson, Boise, ID (US)

Correspondence Address: ENERGY CONVERSION DEVICES, INC., 2956 WATERVIEW DRIVE, ROCHESTER HILLS, MI, 48309, US

(21) Appl. No.: 11/151,556

(22) Filed: Jun. 13, 2005

(51) Int. Cl. G11C 11/00

(52) U.S. Cl. 365/148

(57) ABSTRACT

A method of reading a phase-change memory element. The memory element is read by establishing a read voltage across the memory element. The read voltage is preferably greater than the holding voltage of the memory element.

### FIELD OF THE INVENTION

The present invention relates generally to phase-change memory elements. More specifically, the present invention relates to the reading of electrically programmable phase-change memory elements.

### BACKGROUND OF THE INVENTION

Programmable resistance memory elements formed from materials that can be programmed to exhibit at least a high or low ohmic state are known in the art. Such programmable resistance elements may be programmed to a high resistance state to store, for example, a logic ZERO data bit or programmed to a low resistance state to store a logic ONE data bit.

The use of electrically programmable phase-change materials (for example, materials which can be electrically programmed between amorphous and crystalline states) for electronic memory applications is well known in the art and is disclosed, for example, in commonly assigned U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein. Still another example of a phase-change memory element is provided in commonly assigned U.S. patent application Ser. No. 09/276,273, the disclosure of which is incorporated by reference herein.

Generally, phase-change materials are capable of being electrically programmed between a first structural state where the material is generally amorphous and a second structural state where the material is generally crystalline. The term “amorphous”, as used herein, refers to a condition which is relatively structurally less ordered or more disordered structure than a single crystal. The term “crystalline”, as used herein, refers to a condition which is relatively more ordered than amorphous. The phase-change material exhibits different electrical characteristics depending upon its state. For instance, in its more ordered state the material exhibits a lower electrical resistivity than in its less ordered state.

Materials that may be used as a phase-change material include alloys of the elements from group VI of the Periodic Table. These group VI elements are referred to as the chalcogen elements and include the elements Te and Se. Alloys that include one or more of the chalcogen elements are referred to as chalcogenide alloys. An example of a chalcogenide alloy is the alloy Ge₂Sb₂Te₅.

### SUMMARY OF THE INVENTION

One aspect of the present invention is a method of reading a phase-change memory element, comprising: providing a phase-change memory element, the memory element having a holding voltage and a threshold voltage; and establishing a voltage across the memory element, the voltage being greater than the holding voltage.

Another aspect of the present invention is a method of reading a phase-change memory element, comprising: providing a phase-change memory element, the memory element having a holding voltage and a threshold voltage; applying a controlled current through the memory element; and limiting the voltage across the memory element to be less than the threshold voltage.

Another aspect of the present invention is a memory system, comprising: a phase-change memory element; a read circuit coupled to the phase-change memory element, the read circuit providing a controlled current through the memory element, the read circuit limiting the voltage across the memory element below a predetermined value.

Another aspect of the invention is a memory system, comprising: a phase-change memory element; a controlled current source providing a current to the memory element, and a voltage limiting circuit limiting the voltage across the memory element below a predetermined value.

### BRIEF DESCRIPTION OF THE DRAWINGS

FIG. 1 is an example of a current-resistance curve of a chalcogenide-based phase-change memory element;

FIG. 2 is an example of a current-voltage curve for a chalcogenide-based phase-change memory element in the reset state;

FIG. 3 is an example of a current-voltage curve for a chalcogende-based phase-change memory element in the set state; and

FIG. 4 is an embodiment of a memory system including a programmable resistance memory array and a reading circuit for determining the states of each of the memory elements of the array.

### DETAILED DESCRIPTION OF THE INVENTION

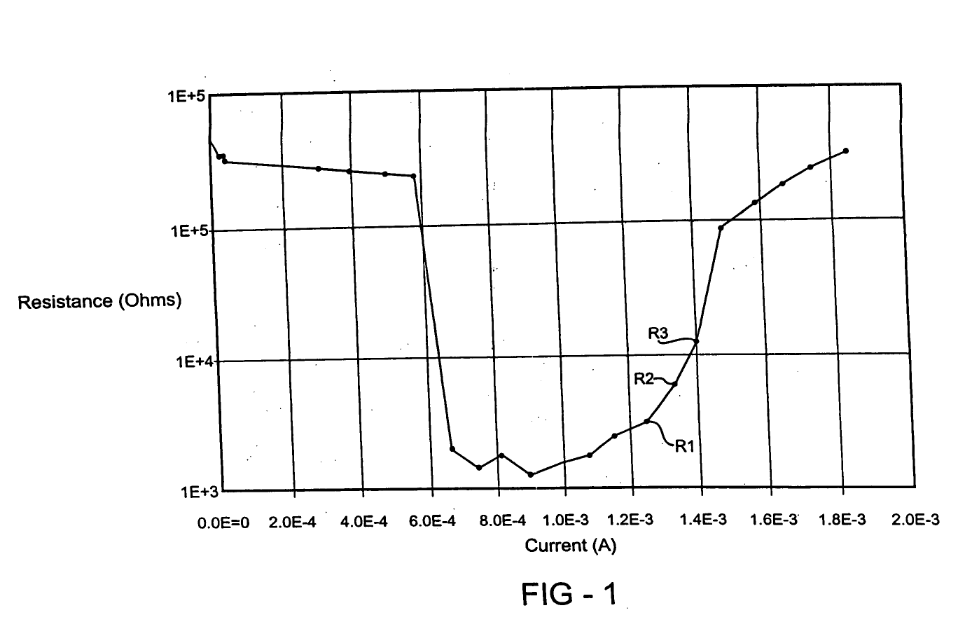

FIG. 1 is a plot of the resistance of a chalcogenide phase-change memory element versus the amplitude of a current pulse through the memory element. Referring to the left side of the curve in FIG. 1, the resistance of the device remains substantially constant at its high resistance or reset state until a sufficient energy is applied to the memory element. The memory element is then transformed from its high resistance or reset state to its low resistance or set state. A pulse of energy (e.g., electrical energy such as electrical current) sufficient to program the memory element from the reset state to the set state is referred to as a set pulse. While not wishing to be bound by theory, it is believed that the set pulse is sufficient to change at least a portion of the volume of memory material from a less-ordered amorphous state to a more-ordered crystalline state. Preferably, the set pulse is a pulse of electrical energy such as a current pulse. Electrical energy may be electron-beam energy. Other forms of energy such as optical energy, acoustical energy or thermal energy may be used.

The memory element may be programmed back from the set state to the reset state. A pulse of energy (such as electrical energy) sufficient to program the memory element from the set state to the reset state is referred to as a reset pulse. While not wishing to be bound by theory, it is believed that application of a reset pulse to the memory element is sufficient to change at least a portion of the volume of memory material from a more-ordered crystalline state to a less-ordered amorphous state. Preferably, the reset pulse is a pulse of electrical energy such as a current pulse. The electrical energy may be electron-beam energy. Other forms of energy such as optical energy, acoustical energy or thermal energy may be used. The memory device may be programmed back and forth between the higher resistance reset state and the lower resistance set state. This type of programming scheme provides for a binary mode of operation (for example, the reset state may be a logic 0 while the set state may be a logic 1).

Referring to the right side of the curve shown in FIG. 1, as the amplitude of the current through the memory element increases, the resistance of the device increases. This increase is both gradual and reversible. In this regime, the phase-change memory element may be programmed to any resistance value within a window of resistance values bounded by the set state and the reset state. More specifically, in this regime along the right side of the curve, the phase-change memory element may be reversibly programmed from any one of the resistance states on the right side of the resistance curve to any other of the resistance states on the right side of the curve by the application of a current pulse of sufficient amplitude. The device may thus be programmed between three or more resistance values within the resistance window so as to provide for multi-state, directly overwritable data storage. With at least three resistance states, each of the memory elements is capable of storing more than one bit of information. Preferably, a multi-state memory element stores two or more bits of information. While not wishing to be bound by theory, it is believed that each of the resistance states along the right side of the curve may correspond to a particular ratio of the volume of crystalline material to the volume of amorphous material in an active region of the phase-change material. As a particular example, three intermediate resistance states R1, R2 and R3 are shown in the resistance curve of FIG. 1.

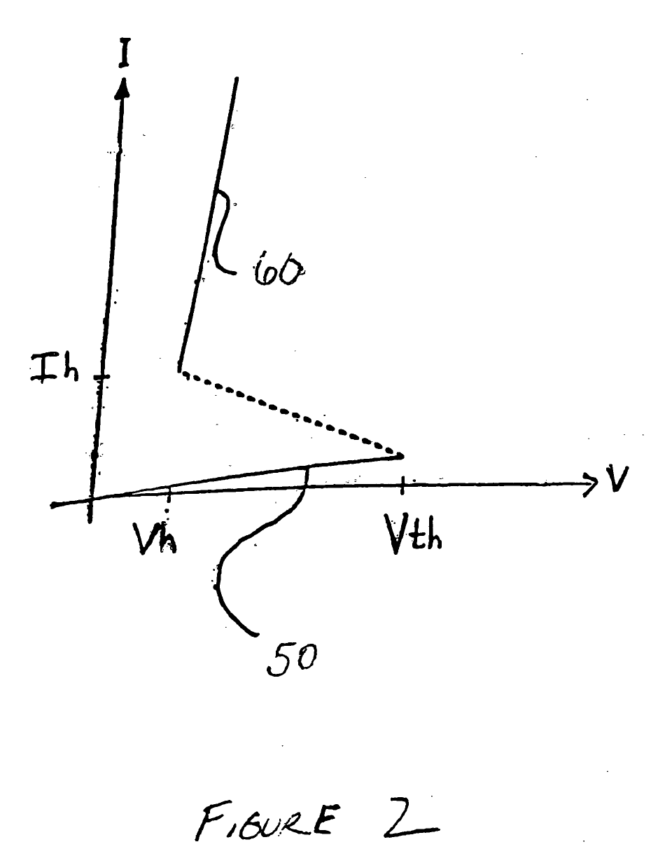

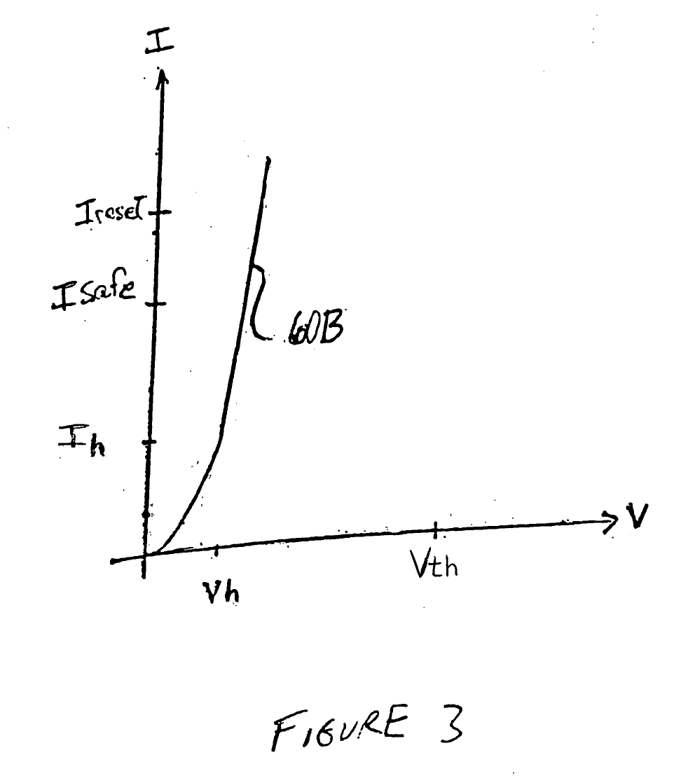

Associated with a chalcogenide phase-change memory element in a particular resistance state is a current-voltage (I-V) characteristic curve. The I-V characteristic curve describes the relationship between the current through the memory element as a function of the voltage across the device. The memory element has a different I-V characteristic curve for the reset state and for the set state. The IV characteristic curve for the reset state is shown in FIG. 2 while the IV characteristic curve for the set state is shown in FIG. 3.

FIG. 2 shows a current-voltage (I-V) graph of a chalcogenide-based phase-change memory element corresponding to the reset state. The graph includes a first branch 50 and a second branch 60. The first branch 50 corresponds to a higher resistance branch in which the current passing through the memory device increases only slightly with increasing voltage across the device. The second branch 60 corresponds to a dynamic lower resistance branch in which the current passing through the device increases significantly with increasing voltage.

When conditions are such that the current through the device and the voltage across the device is described by a point on the first branch 50, the device is in its reset state. When the voltage across the memory element is below the threshold voltage Vth, the memory element remains in the reset state. When the voltage across the memory element reaches or exceeds the threshold voltage Vth, the device switches from the first branch 50 to the second branch 60. On the second branch 60, the memory element becomes highly conductive. However, as long as the energy applied to the memory element remains below that needed to program the memory element to its set state, the memory element should remain in the reset state and when the current is brought down below the holding current Ih, the memory element returns to the first branch 50. The memory element remains on the first branch 50 until another voltage having an amplitude greater than or equal to the threshold voltage Vth is applied. Repeated reads without refreshing the bit by writing may degrade the reset resistance.

For an electronic circuit normally operating at 3V, the threshold voltage Vth may be around 1 volt while the values of the holding voltage Vh may be about 0.4 volts to about 0.5 volts. In addition, the value of resistance of the first branch 50 may be around 200,000 ohms (corresponding the resistance of the high resistance state) while the value of dV/dI on the second branch 60 may be around 1000 ohms (corresponding to the resistance of the lower dynamic resistance state). These values may depend, for example, on the size of the contact to the phase-change material as well as the composition of the phase-change material. The I-V characteristic of the second branch 60 may be expressed analytically as Vh+dV/dI×current through the device. The holding voltage Vh is typically found by the imaginary straight line extension of the second branch 60 to the X axis.

To prevent accidentally programming the memory element from its reset state to its set state, the voltage across the memory element may be limited to less than Vth at times other than when the memory element is actually being programmed. The threshold voltage Vth is dependent upon the thickness of the layer of phase-change memory material, hence varying the thickness may be used to adjust Vth for the range of the operating power supply voltage (e.g. Vcc). For example, for an operating power supply voltage of about 2.7 to 3.3V, the threshold voltage Vth may be adjusted to about 1V or even higher.

As discussed, when the voltage across the phase-change programmable connection reaches or exceeds the threshold voltage Vth, the device switches from the first branch 50 to the second branch 60. After the device has switched to the second branch 60, if a sufficient energy is applied to the memory element, the memory element will be programmed from the reset state to the set state. The applied energy may be a set pulse having a slow trailing edge. The memory element will then operate on the IV characteristic curve of the set state.

An example of an IV characteristic curve of the set state is the curve 60B shown in FIG. 3. FIG. 3 is an I-V curve showing a branch 60B which is similar to second branch 60 of FIG. 2 except that it extends, for voltages below Vh, to the origin. When the memory element has been programmed to its set state it operates on branch 60B of FIG. 3. It remains on branch 60B until it is programmed back to the reset state. For relatively lower voltages, such as less than Vh, the resistance of the device in its set state may be around 5000 ohms to around 10,000 ohms. The set resistance may go even lower (toward about 1000 ohms) as the voltage drop across the device approaches and exceeds the holding voltage Vh (where the slope dV/dI along the curve 60B decreases).

As noted, the memory element remains in its set state and operates on branch 60B until it is programmed back to its reset state. That may be done by applying a current pulse of a sufficient amplitude Ireset and for a sufficient time. The current pulse may have a fast trailing edge (for example, less than 10 nsec) to assist achieving higher reset resistance.

When the memory element is operating in the set state, care must be taken to limit the current through the memory element to a level below Ireset unless it is actually desired to program the memory element to its reset state. To lower the chance of accidentally programming the memory element, Ireset may be increased by, for example, increasing the size of the contacts between the conducting layers and the phase-change material of the memory element.

To ensure against accidentally programming the memory element from its set state to its reset state, the current through the device may be kept below a level Isafe where Isafe is below Ireset. The value of Isafe may be about 70% that of Ireset or less. Isafe may even be set to about 50% (or less) of Ireset to guard against noise and transients (preferably, the transient edge rate applied to any X or Y line coupled to the memory element is slow enough so that the voltage drop across the memory element does not cause the current through the memory element to exceed the value of Isafe).

One way to increase the accuracy of reading a programmable resistance memory element is to increase the difference (i.e. margin) between the resistance of the memory element in the set state and the resistance in the reset state. This increased resistance margin results in an increased margin between the sense signal when reading the set state and the sense signal when reading the reset state.

Referring to FIG. 2 and FIG. 3, it is seen that the resistance margin between the reset state (FIG. 2) and set state (FIG. 3) may be increased by increasing the voltage Vread applied across the memory element when the memory element is being read. Referring to FIG. 3, it is seen that the resistance of the memory element in the set state (along branch 60B shown in FIG. 3) decreases sharply (e.g., the slope increases sharply) when the voltage across the memory element goes above the holding voltage Vh. However, referring to FIG. 2, it is seen that the resistance of the memory element in the reset state (along branch 50 shown in FIG. 2) decreases only very slightly (e.g., the slope increases very slightly) as the voltage across the memory element goes above the holding voltage Vh. Hence, increasing the read voltage Vread above the holding voltage Vh increases the resistance difference between the set and reset states thereby increasing the voltage sense margin between the sense voltages of the two states.

Hence, a method of reading the memory element is to apply a read voltage across the memory element that is greater than the holding voltage. In order to prevent accidental programming of the memory element from its reset state to its set state, it is preferable to limit the read voltage to be less than the threshold voltage of the memory element. Additionally, in order to prevent accidentally programming the memory element from its set state to its reset state, it is preferable to limit the current through the memory element during the read operation to be less than the reset current Ireset (the current required to program the memory element from its set state to its reset state). More preferably, the current during read is limited to a current which is at or below a current Isafe where the current Isafe is less than Ireset. In one embodiment Isafe may be chosen to be about 70% (or less) that of Ireset. In another embodiment Isafe may be chosen to be about 50% (or less) that of Ireset.

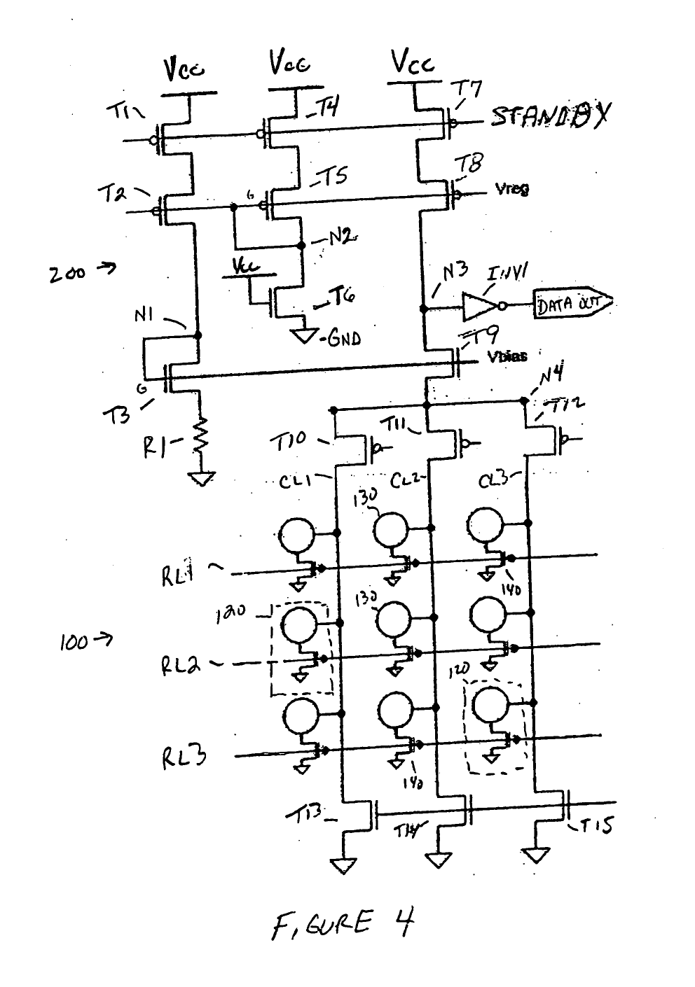

The current through the memory element during a read operation may be limited by placing a current source in the drain of the read transistor used to force the voltage into the selected column. An embodiment of a memory system of the present invention is shown in FIG. 4. The memory system shown in FIG. 4 includes a memory array 100 of phase-change memory cells 120. The array includes three column lines CL1 through CL2 as well as three row lines RL1 though RL3. The column lines may also be referred to as bit lines while the row line may also be referred to a word lines. Generally, the number of row lines and number of column lines is not limited to any particular number. Hence, there may be one or more rows lines and one or more column lines. Preferably, there are at least two row lines. Preferably, there are at least two column lines.

Each memory cell 120 includes a phase-change memory element 130 and an NMOS transistor 140 which serves as an access device. One terminal of the memory element is coupled to a column line while the opposite terminal is coupled to the drain of the transistor 140. The source of the transistor 140 is coupled to ground while the gate of the transistor is coupled to the row line. The order of these connections and the type of transistor or access device may be changed, as is familiar to those reasonably skilled in the art. Other types of access devices are also possible. Examples of access devices include transistors (such as NMOS and PMOS transistors), diodes and chalcogenide threshold switches. Referring to FIG. 4, it is seen that each column line CL1, CL2 and CL3 is coupled to ground through a corresponding NMOS transistor T13, T14 and T15, respectfully.

The memory system shown in FIG. 4 further includes a read circuit 200. The read circuit 200 controls the current though and the voltage across each of the memory elements during a read operation. The read circuit may be used to limit the current through the selected column and cell. The read circuit 200 includes transistors T1 through T9, resistor R1, and inverter gate INV1. PMOS transistors T1 and T2 are serially coupled between the bias voltage Vcc and the drain of NMOS transistor T3 at node N1. The drain and gate of transistor T3 are coupled together. The source of transistor T3 is coupled to ground through resistor R1. PMOS transistors T4 and T5 are coupled in series between the voltage Vcc and the drain of NMOS transistors T6 at node N2. The drain of transistor T6 is coupled to the gate and drain of transistor T5, the source of transistor T6 is coupled to ground (GND) and the gate is coupled to voltage Vcc. Likewise, PMOS transistors T7 and T8 are coupled in series between the voltage Vcc and the drain of NMOS transistor T9 at node N3. The source of NMOS transistor T9 is coupled to node N4.

Transistors T10, T11 and T12 are switches that selectively couple the read circuit 200 at node N4 to the column lines CL1 though CL3, respectfully. The input of inverter gate INVL is coupled to node N3. The read circuit 200 generates a DATA OUT output signal, determined by the resulting amplitude level on node N3 as an input to the logic gate inverter INV1. The N-channel and P-channel devices may be adjusted to raise the threshold at which the logic gate inverter INV1 switches (such as by increasing the size of the P-channel transistors). It is noted that the inverter gate INV1 may be replaced with an amplifier. Any form of voltage sensing circuit may be coupled to node N3. The voltage sensing circuit may comprise an inverter and/or an amplifier.

Transistors T1, T4 and T7 are switches which may be turned on and off depending on the value of the STANDBY signal coupled to the gates of the transistors. When the STANDBY input is HIGH, the PMOS transistors T1, T4 and T7 are all turned OFF and power is saved, such as when a read operation is not requested. Likewise, when the STANDBY input is LOW, the PMOS transistors T1, T4 and T7 are all turned ON.

Transistors T5 and T6 are used to create the desired voltage Vreg that is applied to the gate of transistor T8. Alternately, Vreg may be generated using an on-chip voltage regulator, such as a bandgap regulator. Transistor T2, transistor T3 and resistor R1 are used to create the desired voltage Vbias applied to the gate of transistor T9.

The value of Vreg and the transistor T8 creates a read current Iread. Hence, the transistor T8 serves as a current source providing a predetermined current to the selected memory element being read. Preferably, the read current Iread is chosen to be less than Ireset. More preferably, the read current Iread is chosen to be at or below the current Isafe (shown in FIG. 3). As noted above, the value of Isafe is less than the value of Ireset. In one embodiment the value of Iread may be chosen to be at about 40 micro-amps (ua).

The value of Vbias and the transistor T9 ensure that the voltage across the memory element during a read operation do not exceed a predetermined value. Hence, T9 behaves as a voltage limiting circuit. For example, it may be desired that the voltage across the memory element does not exceed a value Vread. In this case, Vbias may be chosen to be equal to Vread+Vt (N-channel)+Von (Iread) of transistor T9, where Vt is the gate to source threshold voltage for the NMOS transistor T9 and Von is the excess gate to source voltage necessary for the transistor T9 to support a current of Iread. With Vbias so chosen, the transistor T9 will remain ON provided that the voltage at node N4 (also the voltage across a selected memory element) does not exceed the value of Vread. Vread may be selected to be below the threshold voltage Vth of the memory element. Vread may be selected to be above the holding voltage Vh of the memory element. Vread may be chosen to be above Vh but less than Vth. As an example, Vread may be chosen to be at or above 0.4 volts. As another example, Vread may be chosen to be between about 0.4 volts and about 0.5 volts. In yet another example, Vread may be chosen to be at or above about 0.5 volts.

When the accessed memory element 130 is in the lower resistance set state, the voltage drop across the corresponding memory cell 120 will be lower and the voltage at node N4 will also be lower. The transistor T9 will be ON and conducting so that the voltage at node N3 will be forced lower to a logic LOW. However, when the accessed memory element is in the higher resistance reset state, the voltage drop across the corresponding memory cell 120 will go higher. When the voltage across the memory cell 120, and hence the voltage at node N4, goes sufficiently high, the transistor T9 will turn OFF and become not conducting. In this case, the voltage at node N3 will be forced higher to a logic HIGH.

As noted above, the transistor T8 serves as a current source providing a predetermined read current to the selected memory element being read. An ideal current source forcing the read current may be used. In addition, a cascade of P-channel devices or other alternatives may be also be used.

Another way to further improve the margin between the set and reset resistance states is to read the memory element twice. The memory element is first read at a first voltage Vread1 (such as 0.4 volts) across the memory element. The memory element is then read at a second voltage Vread2 (such as 0.5 volts) across the memory element. Preferably, Vread1 and/or Vread2 are at or above the holding voltage Vh. More preferably, Vread1 and/or Vread2 are less than Vth. The first current at the first voltage Vread1 is subtracted from the second current at the second voltage Vread2. The difference is then compared to a reference current to determine the state of the memory element.

Writing the memory cell may be achieved by forcing the preferred current or voltage into node N4 by means familiar to those reasonably skilled in the art. For example, two P-channel transistors may be coupled in parallel and this parallel combination may be coupled in series with an additional transistor between the voltage Vcc and node N4. One of the P-channel transistors may be sized to provide a lower current (e.g. to program the memory element to the set state) while the other P-channel transistor may be sized to a provide a higher current (e.g. to program the memory element to the reset state) . The additional transistor may be turned on when a write operation is desired and turned off when a no write operation is desired.

The memory elements 120 shown in FIG. 4 include a phase-change memory material. The phase-change materials may be any phase change memory material known in the art. Preferably, the phase change materials are capable of exhibiting a first order phase transition. Examples of materials are described in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein.

The phase-change materials may be formed from a plurality of atomic elements. Preferably, the memory material includes at least one chalcogen element. The chalcogen element may be chosen from the group consisting of Te, Se, and mixtures or alloys thereof. The memory material may further include at least one element selected from the group consisting of Ge, Sb, Bi, Pb, Sn, As, S, Si, P, O, and mixtures or alloys thereof. In one embodiment, the phase-change material comprises the elements Ge, Sb and Te. In another embodiment, the memory material consists essentially of Ge, Sb and Te. An example of a phase-change material which may be used is Ge₂Sb₂Te₅.

It is to be understood that the disclosure set forth herein is presented in the form of detailed embodiments described for the purpose of making a full and complete disclosure of the present invention, and that such details are not to be interpreted as limiting the true scope of this invention as set forth and defined in the appended claims.

We claim:

1. A method of reading a phase-change memory element, comprising:
providing a phase-change memory element, said memory element having a holding voltage and a threshold voltage; and
establishing a voltage across said memory element, said voltage being greater than the holding voltage.

2. The method of claim 1, wherein said voltage is less than the threshold voltage.

3. The method of claim 1, wherein the current through said memory element is less than the current necessary to program said memory element from its set state to its reset state.

4. The method of claim 1, wherein said voltage is established by applying a controlled current through said memory element.

5. The method of claim 4, wherein said controlled current is constant.

6. The method of claim 1, wherein said memory element comprises a chalcogen element.

7. A method of reading a phase-change memory element, comprising:
providing a phase-change memory element, said memory element having a holding voltage and a threshold voltage;
applying a controlled current through said memory element; and
limiting the voltage across said memory element to be less than said threshold voltage.

8. The method of claim 7, wherein the voltage across said memory element is greater than the holding voltage.

9. The method of claim 7, wherein said controlled current is less than the current needed to program said memory element from its set state to its reset state.

10. The method of claim 7, wherein said controlled current is constant.

11. The method of claim 7, wherein said phase-change material comprises a chalcogen element.

12. A memory system, comprising:
a phase-change memory element;
a read circuit coupled to said phase-change memory element, said read circuit providing a controlled current through said memory element, said read circuit limiting the voltage across said memory element below a predetermined value.

13. The memory system of claim 12, wherein said read circuit includes a current source providing said controlled current to said memory element.

14. The memory system of claim 12, wherein said read circuit comprises a current limiting circuit for ensuring that the voltage across said memory element does not exceed a predetermined value.

15. The memory system of claim 13, wherein said current source comprises a current mirror.

16. The memory system of claim 13, wherein said current source comprises a first MOS transistor.

17. The memory system of claim 14, wherein said current limiting circuit comprises a second MOS transistor.

18. A memory system, comprising:
a phase-change memory element;
a controlled current source providing a current to said memory element, and
a voltage limiting circuit ensuring that the voltage across said memory element does not exceed a predetermined value.

19. The memory system of claim 18, wherein said controlled current source is in series with said voltage limiting circuit.

20. The memory system of claim 18, wherein said controlled current source comprises a first MOS transistor and said voltage limiting circuit comprises a second MOS transistor, said second MOS transistor is series with said first MOS transistor.

21. The memory system of claim 18, further comprising a voltage sensing circuit coupled to a node between said controlled current source and said voltage limiting circuit, said voltage sensing circuit sensing the voltage at said node.

22. The memory system of claim 21, wherein said voltage sensing circuit comprises an inverter.

23. The memory system of claim 21, wherein said voltage sensing circuit comprises an amplifier.

24. The memory system of claim 18, wherein said phase-change memory element comprises a chalcogen element.
